(19) United States
(12) Patent Application Publication
(10) Pub. No.: US 2005/0007474 A1
(43) Pub. Date: Jan. 13, 2005

(54) Solid-state imaging device

(76) Inventor: Atsushi Maeda, Tokyo (JP)

Correspondence Address: MCDERMOTT WILL & EMERY LLP, 600 13TH STREET, N.W., WASHINGTON, DC, 20005-3096, US

(21) Appl. No.: 10/860,652

(22) Filed: Jun. 4, 2004

(30) Foreign Application Priority Data
Jun. 5, 2003 (JP) JP2003-160766

(51) Int. Cl. H04N 5/335

(52) U.S. Cl. 348/308

(57) ABSTRACT

A light shielding film having a reticular structure that a light shield is placed in a reticular pattern is placed on a main surface of the interlayer insulating film corresponding to an upper part of a N type source region constitutindeviationhoto diode and a P type impurity region. A pattern of the light shielding film in a plane view has a reticular structure that rectangular light shields are placed alternately in a matrix pattern.

### BACKGROUND OF THE INVENTION

1. Field of the Invention

The present invention relates to a solid-state imaging device, and more particularly, it relates to a solid-state imaging device having an ineffective pixel region detecting an optical black.

2. Description of the Background Art

A CCD (charge-coupled device) as described in Japanese Patent Application Laid-Open No. 2001-230402 (FIGS. 1 and 2) is an example of a solid-state imaging device. In that application, a composition placing a light shielding film in an effective pixel region and an ineffective pixel region and placing an opening part in the light shielding film in a part corresponding to an upper part of a light receiving part to obtain a solid-state imaging device in which a black level in the effective pixel region detecting an optical information of an object does not differ from that in the ineffective pixel region detecting the optical black.

Generally, in a manufacturing process of a semiconductor device such as the solid-state imaging device and so on, a surface of the semiconductor substrate is damaged by being exposed to plasma in various processes such as an etching of a gate electrode, for example, and a level which becomes a source of generation of a leakage current is formed occasionally. This level can be terminated by being exposed to hydrogen or an ion including hydrogen in the same manufacturing process of the semiconductor device, and in that case, generation of the leakage current can be suppressed.

However, the light shielding film is generally composed of a material having an effect of absorbing or shielding a hydrogen group such as TiW and so on, thus an effect to terminate the level which becomes the source of generation of the leakage current cannot sufficiently be obtained in a region in which the light shielding film is formed.

Moreover, with regard to the solid-state imaging device, the light shielding film is generally placed only in the ineffective pixel region instead of being placed in the effective pixel region, thus the effect to terminate the level which becomes the source of generation of the leakage current cannot sufficiently be obtained in the ineffective pixel region, and a terminal rate of the level of the surface of the semiconductor substrate in the ineffective pixel region differs from that in the effective pixel region. As a result, the level of the leakage current in a light shielding state in the ineffective pixel region differs from that in the effective pixel region, and either output becomes too large or too small.

In general, the output of the ineffective pixel region becomes a basis of the black level (an element output in a state that light is not irradiated) of an image in the solid-state imaging device, and in case of taking an image actually, a noise component of a signal is removed by deducting the output of the ineffective pixel region from the output of the effective pixel region. Accordingly, it is desirable that the output of the ineffective pixel region accords with the output of the effective pixel region in the state that light is not irradiated.

However, in case that the level of the leakage current in the light shielding state in the ineffective pixel region differs from that in the effective pixel region, and in case that the output of the ineffective pixel region is larger, for example, there is a problem that a picture quality decreases, since even an effective signal component is removed when deducting the output of the ineffective pixel region from the output of the effective pixel region.

### SUMMARY OF THE INVENTION

It is an object to obtain a solid-state imaging device that a level of a surface of a substrate which becomes a source of generation of a leakage current is terminated with employing effectively a hydrogen group generated in a manufacturing process without losing a light shielding effect.

An aspect of a solid-state imaging device according to the present invention includes a photoelectric conversion accumulation part converting an incident light into an electric signal and accumulating a generated electric charge and at least one layer of light shielding film provided above the photoelectric conversion accumulation part, and a plane composition of at least one layer of light shielding film has a composition that light shields and space parts are arranged regularly.

According to the solid-state imaging device described above, the plane composition of at least one layer of light shielding film provided above the photoelectric conversion accumulation part has the composition that the light shields and the space parts are arranged regularly, thus a hydrogen group in an interlayer insulating film covering at least one layer of light shielding film can easily reach a surface of the photoelectric conversion accumulation part through the space parts between the light shields, and a level existing on the surface of the photoelectric conversion accumulation part can be terminated. Moreover, also in case of a hydrogen anneal, the hydrogen group can easily reach the surface of the photoelectric conversion accumulation part, and a termination of the level existing on the surface of the photoelectric conversion accumulation part is promoted more. Accordingly, in case of employing the solid-state imaging device having that light shielding film to an ineffective pixel region detecting an optical black, generation of the leakage current on the surface of the photoelectric conversion accumulation part in the ineffective pixel region can be suppressed, and a difference of the leakage current between that and an effective pixel region detecting an optical information of an object can be resolved, and then an effective signal component is not removed when removing a noise component of a signal by deducting an output of the ineffective pixel region from an output of the effective pixel region, therefore, a decrease of a picture quality of a taken image can be prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a drawing illustrating a circuit composition of a semiconductor device including a CMOS type image sensor.

FIG. 2 is a plane view illustrating a composition of a solid-state imaging device in a preferred embodiment 1 according to the present invention.

FIG. 3 is a cross-sectional view illustrating a composition of the solid-state imaging device in the preferred embodiment 1 according to the present invention.

FIG. 4 is a cross-sectional view illustrating a composition of the solid-state imaging device in a modification example 1 in the preferred embodiment 1 according to the present invention.

FIG. 5 is a cross-sectional view illustrating a composition of the solid-state imaging device in a modification example 2 in the preferred embodiment 1 according to the present invention.

FIGS. 6 and 7 are drawings for describing a setting condition of a light shielding film of the solid-state imaging device in the modification example 2 in the preferred embodiment 1 according to the present invention.

FIG. 8 is a plane view illustrating a composition of the solid-state imaging device in a preferred embodiment 2 according to the present invention.

FIG. 9 is a cross-sectional view illustrating a composition of the solid-state imaging device in the preferred embodiment 2 according to the present invention.

FIG. 10 is a cross-sectional view illustrating a composition of the solid-state imaging device in a modification example 1 in the preferred embodiment 2 according to the present invention.

FIG. 11 is a cross-sectional view illustrating a composition of the solid-state imaging device in a modification example 2 in the preferred embodiment 2 according to the present invention.

FIG. 12 is a cross-sectional view illustrating a composition of the solid-state imaging device in a modification example 3 in the preferred embodiment 2 according to the present invention.

FIG. 13 is a cross-sectional view illustrating a composition of the solid-state imaging device in a modification example 4 in the preferred embodiment 2 according to the present invention.

### DESCRIPTION OF THE PREFERRED EMBODIMENTS

In recent years, a solid-state imaging device employing an amplifier type sensor is suggested as one of the solid-state imaging devices. This device has a feature to amplify a signal of light detected in a photoelectric conversion accumulation part in close proximity to the photoelectric conversion accumulation part. A description of a preferred embodiment is based on an example of the amplifier type sensor as the solid-state imaging device, and one example of a circuit composition of the amplifier type sensor is described in advance of the description of the preferred embodiment.

### Example of the Circuit Composition of the Amplifier Type Sensor

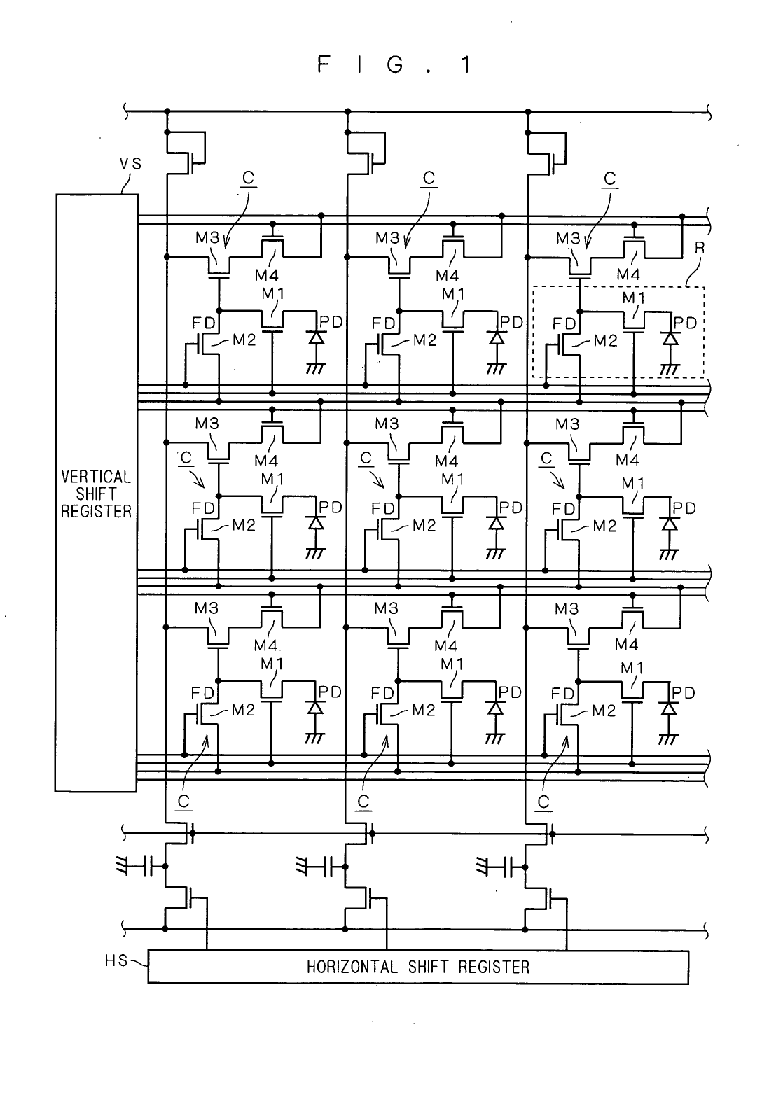

FIG. 1 is a drawing illustrating a circuit composition of a semiconductor device including a CMOS (Complementary Metal Oxide Semiconductor) type image sensor as the solid-state imaging device. As shown in FIG. 1, unit pixels or unit cells C are placed in a matrix pattern, and each unit cell C is connected with a vertical shift register VS and a horizontal shift register HS.

Each unit cell C has a photo diode PD, a transfer switch M1, a reset switch M2, an amplifier M3 and a selective switch M4.

The photo diode PD has a role of a photoelectric conversion accumulation part converting an incident light into an electric signal and accumulating a generated electric charge. The transfer switch M1 has a role of transferring this converted electric signal to the amplifier M3, and it is controlled by a signal from the vertical shift register VS. The reset switch M2 has a role of resetting a signal electric charge, and the amplifier M3 has a role of amplifying the electric signal.

Besides, the transfer switch M1, the reset switch M2, the amplifier M3 and the selective switch M4 are composed of a MOS transistor, respectively.

<A. Preferred Embodiment 1>

<A-1. Composition of the Device>

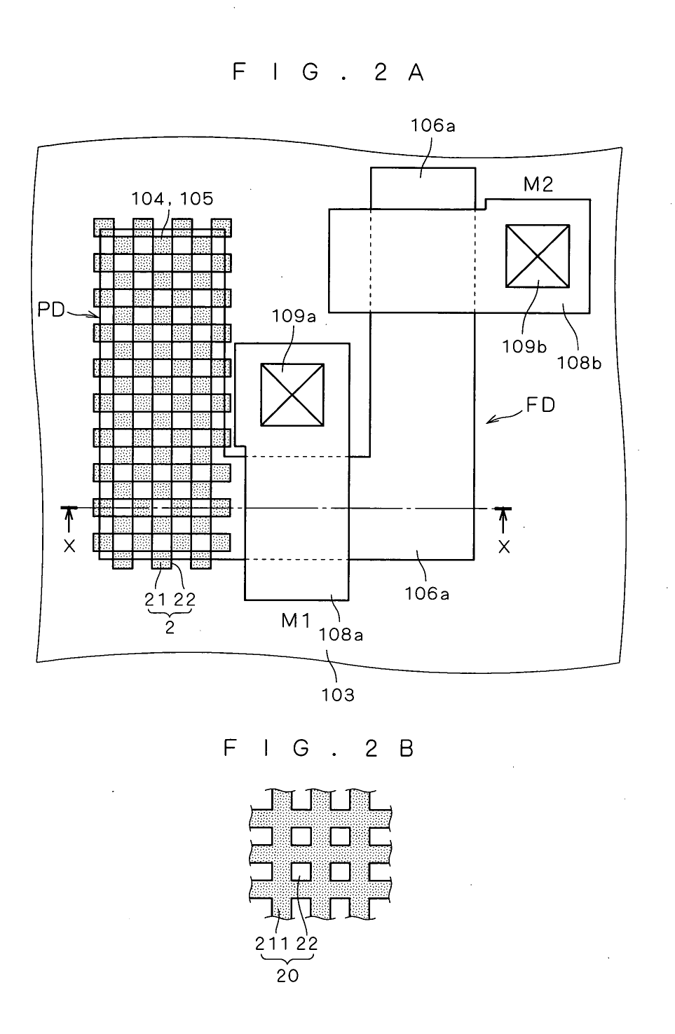

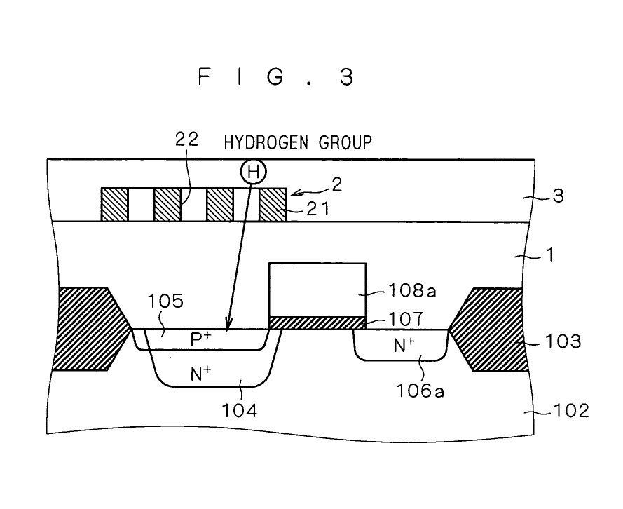

A composition of the semiconductor device including the CMOS type image sensor is described, employing FIGS. 2A and 2B and FIG. 3 with referring to FIG. 1 as the preferred embodiment 1 according to the present invention hereinafter.

FIG. 2A is a plane view illustrating a composition of a region R selected as a representation of an ineffective pixel region detecting an optical black (OB) in the circuit composition illustrated in FIG. 1, and FIG. 3 is an arrow sectional view on a line X-X in FIG. 2A.

As shown in FIG. 2A and FIG. 3, an element isolation insulating layer 103 formed by a LOCOS (Local Oxidation of Silicon) method is placed on a surface of a P type semiconductor substrate 102. Furthermore, the photo diode PD, the transfer switch M1 and the reset switch M2 are placed on the P type semiconductor substrate 102.

The photo diode PD is composed of a PN junction of the P type semiconductor substrate 102 and a N type impurity region 104 (a N type active region) placed in a main surface of the P type semiconductor substrate 102. Moreover, a P type impurity region 105 (a P type active region) shallower than the N type impurity region 104 is placed in the main surface of the P type semiconductor substrate 102 to overlap the N type impurity region 104.

This P type impurity region 105 is formed in such a depth that a depletion layer of the PN junction of the P type semiconductor substrate 102 and the N type impurity region 104 does not reach it.

The transfer switch M1 has a N type source region 104, a N type drain region 106a (a N type active region) and a gate electrode layer 108a. The N type drain region 106a is designated as a FD (Floating Diffusion) since it is in an electrically floating state during action, occasionally.

The N type source region 104 and the N type drain region 106a are placed in the surface of the P type semiconductor substrate 102, keeping a certain distance between them. Moreover, the gate electrode layer 108a is placed on a region between the N type source region 104 and the N type drain region 106a in the P type semiconductor substrate 102 through a gate insulating layer 107. Besides, the N type impurity region 104 in the photo diode PD and the N type source region 104 in the transfer switch M1 are identical regions with each other, and they are referred separately with the object of distinguishing the respective elements.

The reset switch M2 has one couple of N type source/drain regions 106a and a gate electrode layer 108b. One couple of the N type source/drain regions 106a are placed in the surface of the semiconductor substrate 102 to keep a certain distance between them.

Moreover, the gate electrode layer 108b is placed on a region between one couple of the N type source/drain regions 106a in the P type semiconductor substrate 102 through a gate insulating layer (not shown). Besides, the N type drain region 106a in the transfer switch M1 and one of the N type source/drain regions 106a in the reset switch M2 are identical regions with each other, and they are just referred separately with the object of distinguishing the respective elements.

As shown in FIG. 3, an interlayer insulating film 1 is placed on the entire main surface of the P type semiconductor substrate 102, and the gate electrode layer 108a and so on are covered with the interlayer insulating film 1. Moreover, as shown in FIG. 2A, a light shielding film 2 having a reticular structure that a light shield 21 is placed in a reticular pattern is placed on a main surface of the interlayer insulating film 1 corresponding to an upper part of the N type source region 104 constituting the photo diode PD and the P type impurity region 105.

The light shielding film 2 is formed with a material identical with a first wiring layer (not shown) placed on the main surface of the interlayer insulating film 1 in a process identical with that first wiring layer.

Besides, in FIG. 2A, an example of the independent rectangular light shields 21 placed alternately in a matrix pattern and having the reticular structure is illustrated as a shape of the light shielding film 2 with a plane view, however, a structure is not limited to that illustrated in FIG. 2A, when it has a structure that the light shields and space parts are placed regularly.

For example, it is also applicable to place the light shielding film to have the reticular structure by applying a composition that a rectangular space part 22 is surrounded with a continuous light shield 211, the light shield 211 exists between the space part 22 adjacent to each other at four sides of the rectangular space part 22 and the space parts 22 are placed at regular internals in directions of the four sides, respectively, as a light shielding film 20 illustrated in FIG. 2B.

Moreover, as shown in FIG. 3, an interlayer insulating film 3 is placed on the entire main surface of the interlayer insulating film 1, and the light shielding film 2 is covered with the interlayer insulating film 3. Besides, a composition of an effective pixel region detecting an optical information of an object is basically the same with the composition of the ineffective pixel region, however, the light shielding film 2 is not placed on an upper side of the photo diode PD in the effective pixel region.

Here, the interlayer insulating film 3 is formed of a plasma oxide film, and after forming the interlayer insulating film 3, a dangling-bond in silicon generated in a manufacturing process is terminated by performing an anneal treatment (a hydrogen anneal) in a hydrogen atmosphere. Besides, the hydrogen anneal is performed by exposing a semiconductor wafer to one hundred percent hydrogen atmosphere for 15 to 30 minutes under a temperature condition of 400° C. to 450° C.

<A-2. Action and Effect>

The hydrogen group is detached from a SiOH group or a SiH group generated as an in-process material when forming the interlayer insulating film 3 with the plasma oxide film. That is to say, silane (SiH₄) is employed in a plasma oxidation, however, the SiOH group or the hydrogen group is generated by a reaction of SiH₄+O₂→SiOH+H₂O+H, and furthermore, the hydrogen group is detached from the SiOH group, and then numbers of hydrogen groups come to exist in the interlayer insulating film 3.

However, the light shielding film 2 is placed in the reticular pattern on the upper side of the photo diode PD, thus as shown in FIG. 3, the hydrogen group in the interlayer insulating film 3 can easily reach the surface of the photo diode PD through the space parts 22 between the light shields 21, and a level existing on the surface of the photo diode PD can be terminated.

Moreover, also in case of a hydrogen anneal, the hydrogen group can easily reach the surface of the photo diode PD, and a termination of the level existing on the surface of the photo diode PD is promoted more. As a result, generation of a leakage current on the surface of the photo diode PD in the ineffective pixel region can be suppressed, and a difference of the leakage current between that and the effective pixel region in which the light shielding film 2 does not exist can be resolved, and then an effective signal component is not removed when removing a noise component of a signal by deducting an output of the ineffective pixel region from an output of the effective pixel region, therefore, a decrease of a picture quality of a taken image can be prevented.

Besides, it is not necessary that the light shields and the space parts are placed regularly, and a composition that the space parts are placed irregularly at intervals in the light shield is also applicable, with an aspect of making the hydrogen group go through them.

<A-3. Modification Example 1>

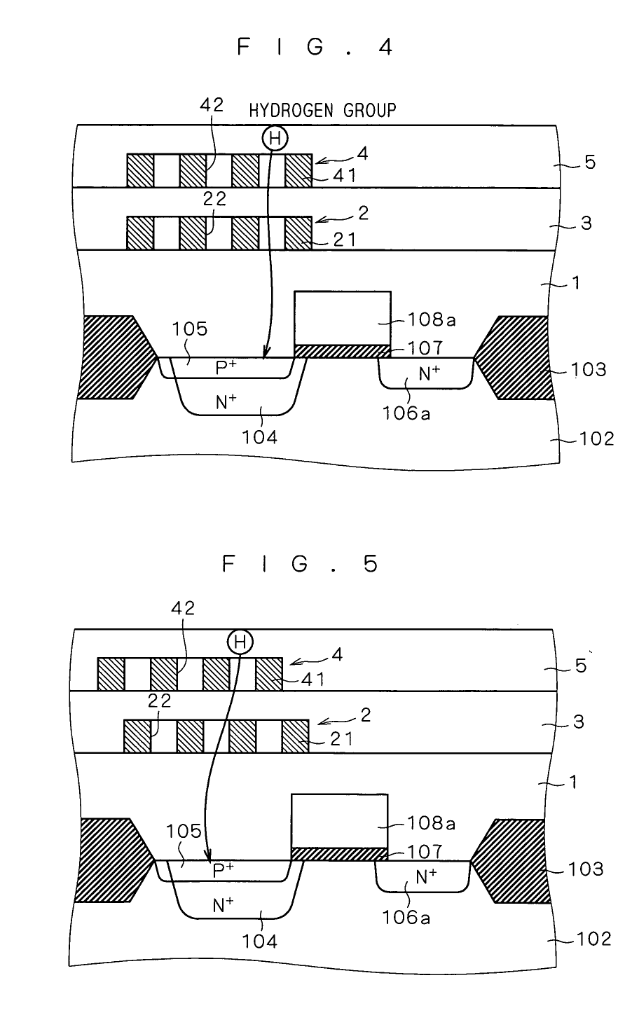

With regard to the composition in the preferred embodiment 1 described above, the composition that the reticular light shielding film 2 is placed on the upper side of the photo diode PD is described, however, a multilayer structure that a light shielding film 4 similar to the light shielding film 2 is further placed on an upper side of the reticular light shielding film 2 is also applicable as shown in FIG. 4. Besides, in FIG. 4, identical codes are put on the compositions identical with the compositions illustrated in FIG. 3, and an overlapped description is omitted.

As shown in FIG. 4, the light shielding film 4 which covers the upper side of the photo diode PD in the same manner as the light shielding film 2 and is formed in the reticular pattern is placed on a main surface of the interlayer insulating film 3 corresponding to the upper side of the light shielding film 2. In the light shielding film 4, in the same manner as the light shielding film 2, light shields 41 are alternately placed in the matrix pattern, and a setting position of the light shields 41 and space parts 42 between the light shields 41 are formed to accord with a setting position of the light shields 21 and the space parts 22 in the light shielding film 2, respectively.

Moreover, an interlayer insulating film 5 is placed on the entire main surface of the interlayer insulating film 3, and the light shielding film 4 is covered with the interlayer insulating film 5. Here, the interlayer insulating film 5 is formed with the plasma oxide film.

Besides, the light shielding film 4 is formed with a material identical with a second wiring layer (not shown) placed on the main surface of the interlayer insulating film 3 in a process identical with that second wiring layer.

By applying such a composition, the hydrogen group detached from the SiOH group or a SiH group generated as the in-process material when forming the interlayer insulating film 5 with the plasma oxide film can easily be made to reach the surface of the photo diode PD through the space parts 42 in the light shielding film 4 and the space parts 22 in the light shielding film 2 and the level existing on the surface of the photo diode PD can be terminated with employing the hydrogen group effectively.

In particular, the setting position of the light shields 41 and the space parts 42 in the light shielding film 4 is formed to accord with the setting position of the light shields 21 and the space parts 22 in the light shielding film 2, thus the hydrogen group can easily go through them, and the hydrogen group can be made to reach the surface of the photo diode PD efficiently.

Besides, in case of forming the interlayer insulating film 5 moreover on the interlayer insulating film 3 as described above, the hydrogen anneal is performed after forming the interlayer insulating film 5 instead of after forming the interlayer insulating film 3, and also in that case, the hydrogen group can easily reach the surface of the photo diode PD, and a termination of the level existing on the surface of the photo diode PD is promoted more, and thus an effect corresponding to a decrease in the leakage current can be increased.

<A-4. Modification Example 2>

Moreover, with regard to the modification example 1 described above, a composition that the setting position of the light shields 41 and the space parts 42 in the light shielding film 4 is formed to accord with the setting position of the light shields 21 and the space parts 22 in the light shielding film 2 is described, however, as shown in FIG. 5, a composition that the light shield 41 and the space part 42 in the light shielding film 4 overlap the upper sides of the space part 22 and the light shield 21 in the light shielding film 2, respectively, is also applicable.

That is to say, in FIG. 5, the light shielding film 4 is placed so that the light shield 41 in the light shielding film 4 exists on the upper side of the space part 22 in the light shielding film 2 and the space part 42 in the light shielding film 4 exists on the upper side of the light shield 21 in the light shielding film 2.

By applying such a composition, it is possible to obscure light entering from a direction vertical to the semiconductor substrate 102 almost entirely by the light shields 21 and 41, and a light shielding effect can remarkably be increased by decreasing light reaching the photo diode PD.

In the meantime, the hydrogen group in the interlayer insulating films 3 and 5 can easily reach the surface of the photo diode PD through the space part 22 in the light shielding film 2 and the space parts 42 in the light shielding film 4, thus the level existing on the surface of the photo diode PD can be terminated without losing the light shielding effect, and the effect corresponding to the decrease in the leakage current can be increased.

Besides, in the description above, the light shielding films 2 and 4 are supposed to be formed in the process identical with the first wiring layer and the second wiring layer, respectively, however, the present invention is not limited to this, and the effect described above can be obtained in case of forming the light shielding film 2 in a process identical with an n-th wiring layer and forming the light shielding film 4 in a process identical with an (n+1)-th wiring layer, one layer upper than the n-th wiring layer.

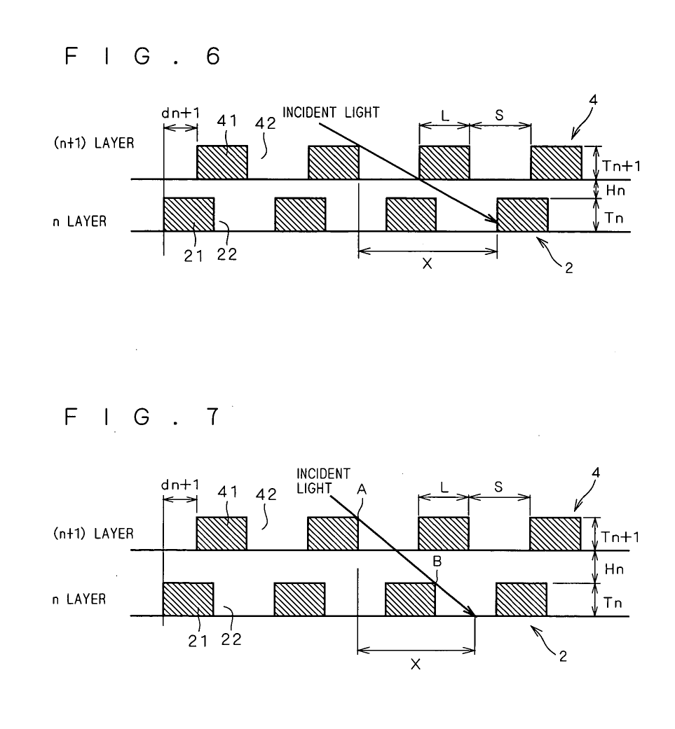

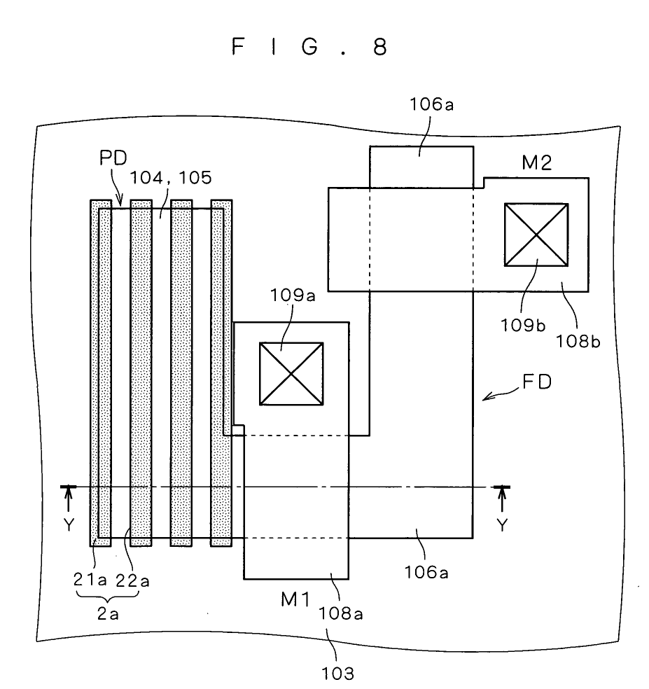

Here, a setting condition of the light shields 21 and 41 which can shield light entering from an oblique direction toward the semiconductor substrate 102 is described with employing FIG. 6 and FIG. 7 on the assumption that the light shielding film 2 is formed in the process identical with the n-th wiring layer and the light shielding film 4 is formed in the process identical with the (n+1)-th wiring layer. Besides, in FIG. 6 and FIG. 7, the setting position of the light shield 41 does not completely accord with the upper part of the space part 22, however, it is an expedient expression to describe the shield of light entering from the oblique direction.

FIG. 6 is a drawing illustrating the setting condition of the light shields 21 and 41 to obscure light entering from the oblique direction by the light shielding film 4 formed in the process identical with mainly the (n+1)-th wiring layer.

In FIG. 6, a thickness Hn of the interlayer insulating film 3 between the light shield 21 and the light shield 41 is thinned down, and a conditional equation in this case is expressed as mathematical expressions (1) and (2) described below.
X:(Tn+Tn+1+Hn)=S:Tn+1 (1)
X<2S+L−dn+1 (2)

With regard to the mathematical expressions (1) and (2) described above, X indicates a length from a position where a straight line extending vertically from an edge part of a specific light shield 41 intersects with the interlayer insulating film 1 to a position where an edge part of the light shield 21 placed in the second when countering from the specific light shield 41 described above as a beginning in a direction of an incident light intersects with the interlayer insulating film 1, and Tn indicates a thickness of the light shield 21, Tn+1 indicates a thickness of the light shield 41, dn+1 indicates a length of a deviation between the light shield 41 and the light shield 21 in a horizontal direction, L indicates a width of the light shields 21 and 41 and S indicates a width of the space parts 22 and 42. A mathematical expression (3) described below can be obtained on the basis of the conditional equations described above.
{S(Tn+Tn+1+Hn)/Tn+1}<(2S+L−dn+1) (3)

It is possible to obscure light entering from the oblique direction by the light shielding film 4 formed in the process identical with mainly the (n+1)-th wiring layer by setting the light shields 21 and 41 to satisfy the mathematical expression (3).

Besides, the light shield 41 is placed so that its setting position accords with the upper part of the space part 22 basically to obscure the incident light right overhead, thus dn+1=L is applied and the mathematical expression (3) can be rewritten as a mathematical expression (4) described below.
{S(Tn+Tn+1+Hn)/Tn+}<2S (4)

FIG. 7 is a drawing illustrating the setting condition of the light shields 21 and 41 to obscure light entering from the oblique direction by the light shielding film 2 formed in the process identical with mainly the n-th wiring layer.

In FIG. 7, the thickness Hn of the interlayer insulating film 3 between the light shield 21 and the light shield 41 is thickened, and a conditional equation in this case is expressed as mathematical expressions (5) and (6) described below.
X:(Tn+Tn+1+Hn)=S+L−dn+1:Tn+1+Hn (5)
X>2S+L−dn+1 (6)

A mathematical expression (7) described below can be obtained on the basis of the conditional equations described above.
{(S+L−dn+1)(Tn+Tn+1+Hn)/(Tn+1+Hn)}>(2S+L−dn+1) (7)

Besides, with regard to the mathematical expressions (5) and (6) described above, X indicates a length from a position where a straight line extending vertically from an edge part of a specific light shield 41 intersects with the interlayer insulating film 1 to a position where a straight line joining an upper corner part A of the specific light shield 41 described above and an upper corner part B of the light shield 21 placed in the first when counting from the specific light shield 41 described above as the beginning in the direction of the incident light (illustrated as a linear incident light in FIG. 7). With regard to the other parameter, the mathematical expressions (5) and (6) have ones identical with the mathematical expressions (1) and (2).

It is possible to obscure light entering from the oblique direction by the light shielding film 2 formed in the process identical with mainly the n-th wiring layer by placing the light shields 21 and 41 to satisfy the mathematical expression (7).

Besides, the light shield 41 is placed so that its setting position accords with the upper part of the space part 22 basically to obscure the incident light right overhead, thus dn+1=L is applied and the mathematical expression (7) can be rewritten as a mathematical expression (8) described below.
{S(Tn+Tn+1+Hn)/(Tn+1+Hn)}>2S (8)

<A-5. Modification Example 3>

In the preferred embodiment 1 and its modification examples 1 and 2 described above, the light shielding films 2 and 4 are supposed to be formed in the process identical with the first wiring layer and the second wiring layer, respectively, however, it is also applicable to form at least the light shielding film 2 in the closest proximity to the photo diode PD in a process different from the wiring layer.

That is to say, the wiring layer is composed with sandwiching an aluminum wiring layer (AlCu and so on) as a center layer between a titanium (Ti) layer and a TiN layer, however, Ti has the nature of absorbing hydrogen, thus the level existing on the surface of the photo diode PD can be terminated efficiently by making more hydrogen reach the surface of the photo diode PD with preventing the absorption of hydrogen by forming at least the light shielding film 2 in the closest proximity to the photo diode PD to have a composition not having a layer including Ti. Besides, it goes without saying that the light shielding film 4 can have a structure similar to the light shielding film 2, too.

As an example of the manufacturing method, with regard to the formation of the wiring layer, a desired light shielding film is obtained by covering entirely a forming region of the light shielding film with a resist film and so on for the purpose of protection in case of forming the wiring layer except for the center layer, removing that resist film in case of forming the center layer, forming the center layer with employing a mask addindeviationattern of the light shielding film to a pattern to form the center layer and covering entirely the forming region of the light shielding film with the resist film and so on for the purpose of protection after forming the center layer.

<B. Preferred Embodiment 2>

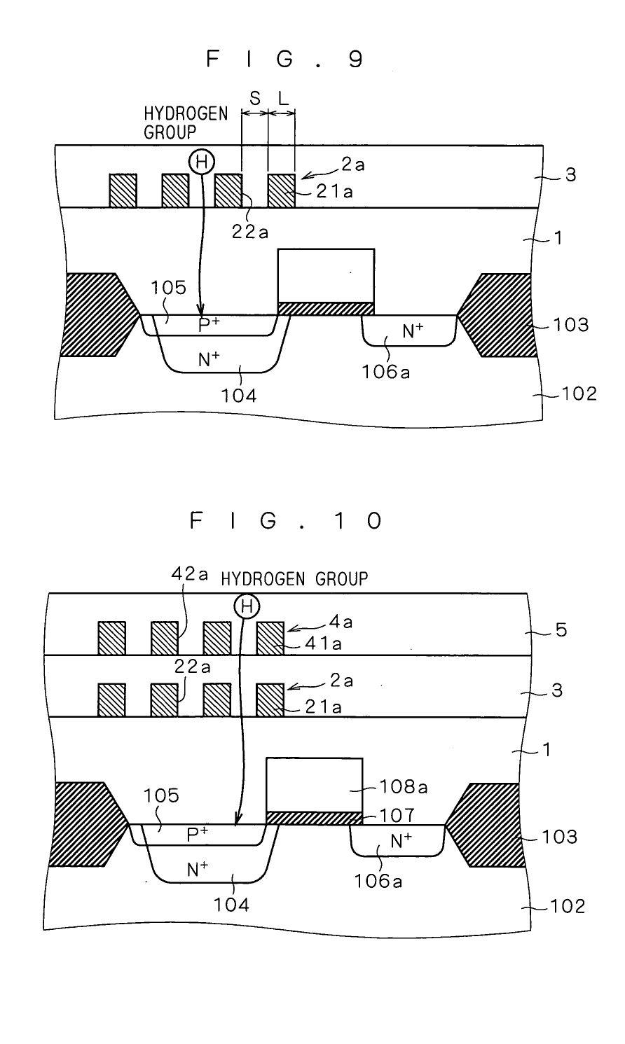

A composition that a striped light shielding film 2a is placed, leaving spaces in it, on the upper side of the photo diode PD is illustrated in FIG. 8 and FIG. 9 as the preferred embodiment 2 according to the present invention. Besides, in FIG. 8 and FIG. 9, identical codes are put on the compositions identical with the compositions illustrated in FIG. 2A and FIG. 3, and an overlapped description is omitted.

<B-1. Composition of the Device>

FIG. 8 is a plane view illustrating a composition of the region R selected as the representation of the ineffective pixel region detecting the optical black in the circuit composition illustrated in FIG. 1, and FIG. 9 is an arrow sectional view on a line Y-Y in FIG. 8.

As shown in FIG. 9, the light shielding film 2a having the striped structure that plural striped light shields 21a are placed in parallel with each other, sandwiching striped space parts 22a between them is placed on the main surface of the interlayer insulating film 1 corresponding to the upper part of the N type source region 104 constituting the photo diode PD and the P type impurity region 105. Besides, a width of the light shield 21a is illustrated as L and a width of the space part 22a is illustrated as S in FIG. 9.

The light shielding film 2a is formed with a material identical with a first wiring layer (not shown) placed on the main surface of the interlayer insulating film 1 in a process identical with that first wiring layer.

Besides, a setting direction of the light shield 21a is illustrated as being in parallel with a gate length direction of the gate electrode layer 108a in FIG. 8 and FIG. 9, however, the light shield 21a can also be placed to be vertical to the gate length direction.

Moreover, as shown in FIG. 9, the interlayer insulating film 3 is placed on the entire main surface of the interlayer insulating film 1, and the light shielding film 2 is covered with the interlayer insulating film 3.

Here, the interlayer insulating film 3 is formed of the plasma oxide film, and after forming the interlayer insulating film 3, the dangling-bond in silicon generated in the manufacturing process is terminated by performing the anneal treatment (the hydrogen anneal) in the hydrogen atmosphere. Besides, the hydrogen anneal is performed by exposing the semiconductor wafer to one hundred percent hydrogen atmosphere for 15 to 30 minutes under the temperature condition of 400° C. to 450° C.

<B-2. Action and Effect>

The hydrogen group is detached from the SiOH group or the SiH group generated as the in-process material when forming the interlayer insulating film 3 with the plasma oxide film, and then numbers of hydrogen groups come to exist in the interlayer insulating film 3, however, the light shielding film 2a having the striped structure that the plural striped light shields 21a are placed in parallel with each other, leaving the spaces between them, is placed on the upper side of the photo diode PD, thus as shown in FIG. 9, the hydrogen group in the interlayer insulating film 3 can easily reach the surface of the photo diode PD through the space parts 22a between the light shields 21a, and the level existing on the surface of the photo diode PD can be terminated. Besides, the formation is easy by making the light shield 21a have the striped structure.

Moreover, also in case of a hydrogen anneal, the hydrogen group can easily reach the surface of the photo diode PD, and a termination of the level existing on the surface of the photo diode PD is promoted more. As a result, generation of a leakage current on the surface of the photo diode PD in the ineffective pixel region can be suppressed, and a difference of the leakage current between that and the effective pixel region in which the light shielding film 2 does not exist can be resolved, and then an effective signal component is not removed when removing a noise component of a signal by deducting an output of the ineffective pixel region from an output of the effective pixel region, therefore, a decrease of a picture quality of a taken image can be prevented.

<B-3. Modification Example 1>

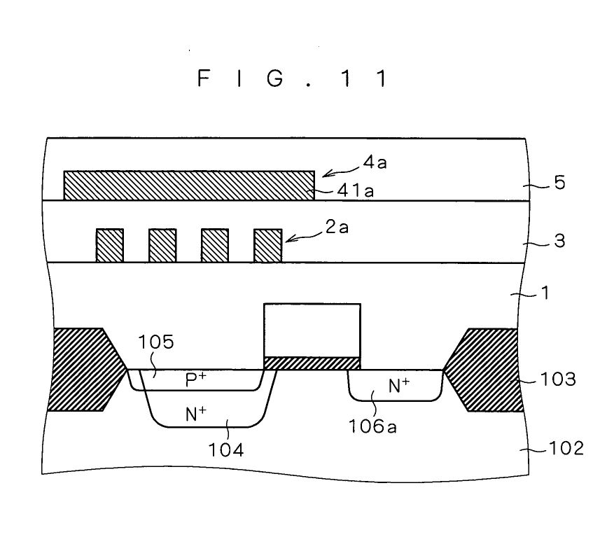

With regard to the composition in the preferred embodiment 2 described above, the composition that the light shielding film 2a having the striped structure is placed on the upper side of the photo diode PD is described, however, a multilayer structure that a light shielding film 4a similar to the light shielding film 2a is further placed on an upper side of the light shielding film 2a is also applicable as shown in FIG. 10. Besides, in FIG. 10, identical codes are put on the compositions identical with the compositions illustrated in FIG. 9, and an overlapped description is omitted.

As shown in FIG. 10, the striped light shielding film 4a which covers the upper side of the photo diode PD in the same manner as the light shielding film 2a is placed on a main surface of the interlayer insulating film 3 corresponding to the upper part of the light shielding film 2a. In the light shielding film 4a, in the same manner as the light shielding film 2a, plural striped light shields 41a are placed in parallel with each other, sandwiching the striped space parts 42a between them, and a setting position of the light shields 41a and space parts 42a between the light shields 41a are formed to accord with a setting position of the light shields 21a and the space parts 22a in the light shielding film 2a, respectively.

Moreover, the interlayer insulating film 5 is placed on the entire main surface of the interlayer insulating film 3, and the light shielding film 4a is covered with the interlayer insulating film 5. Here, the interlayer insulating film 5 is formed with the plasma oxide film.

Besides, the light shielding film 4a is formed with the material identical with the second wiring layer (not shown) placed on the main surface of the interlayer insulating film 3 in the process identical with that second wiring layer.

By applying such a composition, the hydrogen group detached from the SiOH group or a SiH group generated as the in-process material when forming the interlayer insulating film 5 with the plasma oxide film can easily be made to reach the surface of the photo diode PD through the space parts 42a in the light shielding film 4a and the space parts 22a in the light shielding film 2a and the level existing on the surface of the photo diode PD can be terminated with employing the hydrogen group effectively.

Besides, in case of forming the interlayer insulating film 5 moreover on the interlayer insulating film 3 as described above, the hydrogen anneal is performed after forming the interlayer insulating film 5 instead of after forming the interlayer insulating film 3, and also in that case, the hydrogen group can easily reach the surface of the photo diode PD, and the termination of the level existing on the surface of the photo diode PD is promoted more, and thus the effect corresponding to the decrease in the leakage current can be increased.

<B-4. Modification Example 2>

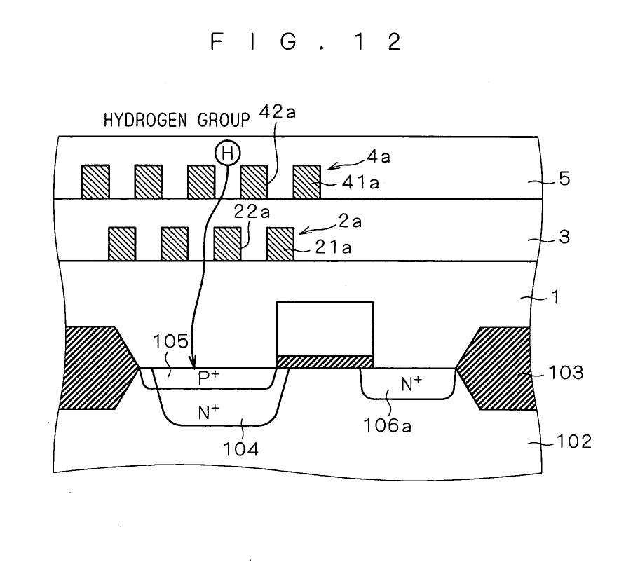

In FIG. 10, an example that the setting direction of the light shield 41a in the light shielding film 4a placed on the upper side of the light shielding film 2a is parallel with the gate length direction of the gate electrode layer 108a, in the same manner as the light shielding film 2a, is illustrated, however, the light shield 41a can also be placed to be vertical to the gate length direction as illustrated in FIG. 11.

That is to say, the light shield 41a in the light shielding film 4a is placed to cross at right angles the setting direction of the light shield 21a in the light shielding film 2a in a plane view as illustrated in FIG. 11.

By applying such a composition, the hydrogen group in the interlayer insulating films 5 and 3 can easily reach the surface of the photo diode PD, and the level existing on the surface of the photo diode PD can be terminated. Moreover, also in case of the hydrogen anneal, the hydrogen group can easily reach the surface of the photo diode PD, and the termination of the level existing on the surface of the photo diode PD is promoted more, and thus the effect corresponding to the decrease in the leakage current can be increased.

Furthermore, a part which is covered with the light shield 41a is formed in the space part 22a in the light shielding film 2a by placing the light shield 41a in the light shielding film 4a to cross at right angles the setting direction of the light shield 21a in the light shielding film 2a in the plane view, and it is possible to obscure most part of light entering from the direction vertical to the semiconductor substrate 102 by the light shields 21a and 41a, and the light shielding effect can remarkably be increased by decreasing light reaching the photo diode PD.

<B-5. Modification Example 3>

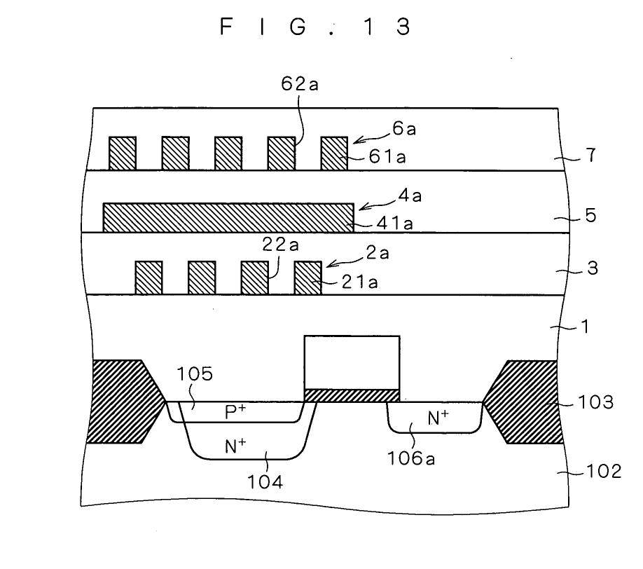

With regard to the modification example 1, a composition that the setting position of the light shields 41a and the space parts 42a in the light shielding film 4a is formed to accord with the setting position of the light shields 21 a and the space parts 22a in the light shielding film 2a is described, however, as shown in FIG. 12, a composition that the light shield 41a and the space part 42a in the light shielding film 4a overlap the upper sides of the space part 22a and the light shield 21 a in the light shielding film 2a, respectively, is also applicable.

That is to say, in FIG. 12, the light shielding film 4a is placed so that the light shield 41a in the light shielding film 4a exists on the upper side of the space part 22a in the light shielding film 2a and the space part 42a in the light shielding film 4a exists on the upper side of the light shield 21 a in the light shielding film 2a.

By applying such a composition, it is possible to obscure light entering from the direction vertical to the semiconductor substrate 102 almost entirely by the light shields 21a and 41a, and the light shielding effect can remarkably be increased by decreasing light reaching the photo diode PD.

In the meantime, the hydrogen group in the interlayer insulating films 3 and 5 can easily reach the surface of the photo diode PD through the space part 22a in the light shielding film 2a and the space part 42a in the light shielding film 4a, thus the level existing on the surface of the photo diode PD can be terminated without losing the light shielding effect, and the effect corresponding to the decrease in the leakage current can be increased.

Besides, in the description above, the light shielding films 2a and 4a are supposed to be formed in the process identical with the first wiring layer and the second wiring layer, respectively, however, the present invention is not limited to this, and the effect described above can be obtained in case of forming the light shielding film 2 in the process identical with the n-th wiring layer and forming the light shielding film 4 in the process identical with the (n+1)-th wiring layer, one layer upper than the n-th wiring layer.

Moreover, a setting condition of the light shields 21a and 41a to obscure light entering from the oblique direction is similar to that of the light shields 21 and 41 described with employing the mathematical expressions (1) to (8).

<B-6. Modification Example 4>

As shown in FIG. 13, it is also applicable to place a light shielding film 6a having a striped structure to cover an upper side of the light shielding film 4a on the main surface of the interlayer insulating film 5 in the composition that the light shield 41a in the light shielding film 4a is placed to cross at right angles the setting direction of the light shield 21a in the light shielding film 2a in the plane view as shown in FIG. 13. The light shielding film 6a has a striped structure that plural striped light shields 61a are placed in parallel with each other, sandwiching the striped space parts 62a between them in the same manner as the light shielding films 2a and 4a. Here, the light shielding film 6a is placed so that a setting position of the light shields 61a and space parts 62a overlap the upper part of the space parts 22a and the light shields 21 a in the light shielding film 2a, respectively.

The light shielding film 6a is formed with the material identical with a third wiring layer (not shown) placed on the main surface of the interlayer insulating film 5 in the process identical with that third wiring layer. Besides, an interlayer insulating film 7 is placed on the entire main surface of the interlayer insulating film 5, and the light shielding film 6a is covered with the interlayer insulating film 7. Here, the interlayer insulating film 7 is formed with the plasma oxide film.

By applying such a composition, it is possible to obscure light entering from the direction vertical to the semiconductor substrate 102 almost entirely by the light shields 21a, 41a and 61a, and a light shielding effect can remarkably be increased by decreasing light reaching the photo diode PD.

Besides, in case of forming the interlayer insulating film 7 moreover on the interlayer insulating film 5 as described above, the hydrogen anneal is performed after forming the interlayer insulating film 7, and also in that case, the hydrogen group can easily reach the surface of the photo diode PD, and the termination of the level existing on the surface of the photo diode PD is promoted more, and thus the effect corresponding to the decrease in the leakage current can be increased.

<B-7. Modification Example 5>

In the preferred embodiment 2 and its modification examples 1 to 4 described above, the light shielding films 2a, 4a and 6a are supposed to be formed in the process identical with the first wiring layer, the second wiring layer and the third wiring layer, respectively, however, it is also applicable to form at least the light shielding film 2a in the closest proximity to the photo diode PD in the process different from the wiring layer.

That is to say, the wiring layer is composed with sandwiching an alloy layer including aluminum (AlSiCu, AlCu and so on) as a center layer between the titan (Ti) layer and a titanium compound (TiN, TiW and so on) layer, however, Ti has the nature of absorbing hydrogen, thus the level existing on the surface of the photo diode PD can be terminated efficiently by making more hydrogen reach the surface of the photo diode PD with preventing the absorption of hydrogen by forming at least the light shielding film 2 in the closest proximity to the photo diode PD to have the composition not having the layer including Ti. Besides, it goes without saying that the light shielding films 4a and 4b can have the structure similar to the light shielding film 2, too. Besides, it goes without saying that this composition can be applied to the light shielding film 2 described in the preferred embodiment 1, too.

As one example of the manufacturing method, with regard to the formation of the wiring layer, the desired light shielding film is obtained by covering entirely the forming region of the light shielding film with the resist film and so on for the purpose of protection in case of forming the wiring layer except for the center layer, removing that resist film in case of forming the center layer, forming the center layer with employing the mask adding the pattern of the light shielding film to the pattern to form the center layer and covering entirely the forming region of the light shielding film with the resist film and so on for the purpose of protection after forming the center layer.

While the invention has been shown and described in detail, the foregoing description is in all aspects illustrative and not restrictive. It is therefore understood that numerous modifications and variations can be devised without departing from the scope of the invention.

1. A solid-state imaging device, comprising:
a photoelectric conversion accumulation part converting an incident light into an electric signal and accumulating a generated electric charge; and
at least one layer of light shielding film provided above said photoelectric conversion accumulation part, wherein
a plane structure of said at least one layer of light shielding film has
a structure that at least one light shield and one space part are arranged regularly.

2. The solid-state imaging device according to claim 1, wherein
said at least one light shield includes independent plural light shields and
a plane structure of said at least one layer of light shielding film has
a reticular structure that said light shield is placed in a reticular pattern so that said space part is placed between said light shields.

3. The solid-state imaging device according to claim 2, wherein
said at least one layer of light shielding film includes plural layers of light shielding film, between which an interlayer insulating film is sandwiched, and
a first layer light shielding film right overhead of said photoelectric conversion accumulation part has a structure not including a titanium layer.

4. The solid-state imaging device according to claim 2, wherein
said at least one layer of light shielding film includes plural layers of light shielding film, between which an interlayer insulating film is sandwiched, and all layers of said plural layers of light shielding film have said reticular structure.

5. The solid-state imaging device according to claim 4, wherein
said plural layers of light shielding film are placed
so that a light shield and a space part in an (n+1)-th layer of light shielding film covers upper sides of a light shield and a space part in an n-th layer of light shielding film, respectively.

6. The solid-state imaging device according to claim 4, wherein said plural layers of light shielding film are placed so that a space part and a light shield in an (n+l)-th layer of light shielding film covers upper sides of a light shield and a space part in an n-th layer of light shielding film, respectively.

7. The solid-state imaging device according to claim 6, wherein
said n-th layer of light shielding film and said (n+1)-th layer of light shielding film are identical with each other in a size S of said space part and in a size L of said light shield, and
where a height of said light shield in said n-th layer of light shielding film is expressed as Tn,
a height of said light shield in said (n+1)-th layer of light shielding film is expressed as Tn+1,
a thickness of said interlayer insulating film between said light shield in said n-th layer of light shielding film and said light shield in said (n+1)-th layer of light shielding film is expressed as Hn, and
a length of a deviation between said light shield in said n-th layer of light shielding film and said light shield in said (n+1)-th layer of light shielding film in a horizontal direction is expressed as dn+1,
said n-th layer of light shielding film and said (n+1)-th layer of light shielding film is placed to satisfy {S(Tn+Tn+1+Hn)/Tn+1}<(2S+L−dn+1).

8. The solid-state imaging device according to claim 6, wherein
said n-th layer of light shielding film and said (n+1)-th layer of light shielding film are identical with each other in a size S of said space part and in a size L of said light shield, and
where a height of said light shield in said n-th layer of light shielding film is expressed as Tn,
a height of said light shield in said (n+1)-th layer of light shielding film is expressed as Tn+1,
a thickness of said interlayer insulating film between said light shield in said n-th layer of light shielding film and said light shield in said (n+1)-th layer of light shielding film is expressed as Hn, and
a length of a deviation between said light shield in said n-th layer of light shielding film and said light shield in said (n+1)-th layer of light shielding film in a horizontal direction is expressed as dn+1,
said n-th layer of light shielding film and said (n+1)-th layer of light shielding film is placed to satisfy {(S+L−dn+1) (Tn+Tn+1+Hn)/(Tn+1+Hn)}>(2S+L−dn+1).

9. The solid-state imaging device according to claim 1, wherein
said at least one light shield includes striped plural light shields,
said space part includes striped plural space parts, and
a plane structure of said at least one layer of light shielding film has
a striped structure that said light shields are placed in parallel with each other to sandwich said space parts between said light shields.

10. The solid-state imaging device according to claim 9, wherein
said at least one layer of light shielding film includes plural layers of light shielding film, between which an interlayer insulating film is sandwiched, and
a first layer light shielding film right overhead of said photoelectric conversion accumulation part has a structure not including a titanium layer.

11. The solid-state imaging device according to claim 9, wherein
said at least one layer of light shielding film includes plural layers of light shielding film, between which an interlayer insulating film is sandwiched, and
all layers of said plural layers of light shielding film have said striped structure.

12. The solid-state imaging device according to claim 11, wherein
said plural layers of light shielding film are placed
so that a light shield and a space part in an (n+1)-th layer of light shielding film covers upper sides of a light shield and a space part in an n-th layer of light shielding film, respectively.

13. The solid-state imaging device according to claim 11, wherein
said plural layers of light shielding film are placed
so that a space part and a light shield in an (n+1)-th layer of light shielding film covers upper sides of a light shield and a space part in an n-th layer of light shielding film, respectively.

14. The solid-state imaging device according to claim 13, wherein
said n-th layer of light shielding film and said (n+1)-th layer of light shielding film are identical with each other in a size S of said space part and in a size L of said light shield, and
where a height of said light shield in said n-th layer of light shielding film is expressed as Tn,
a height of said light shield in said (n+1)-th layer of light shielding film is expressed as Tn+1,
a thickness of said interlayer insulating film between said light shield in said n-th layer of light shielding film and said light shield in said (n+1)-th layer of light shielding film is expressed as Hn, and
a length of a deviation between said light shield in said n-th layer of light shielding film and said light shield in said (n+1)-th layer of light shielding film in a horizontal direction is expressed as dn+1,
said n-th layer of light shielding film and said (n+1)-th layer of light shielding film is placed to satisfy {S(Tn+Tn+1+Hn)/Tn+1}<(2S+L−dn+1).

15. The solid-state imaging device according to claim 13, wherein
said n-th layer of light shielding film and said (n+1)-th layer of light shielding film are identical with each other in a size S of said space part and in a size L of said light shield, and
where a height of said light shield in said n-th layer of light shielding film is expressed as Tn,
a height of said light shield in said (n+1)-th layer of light shielding film is expressed as Tn+1,
a thickness of said interlayer insulating film between said light shield in said n-th layer of light shielding film and said light shield in said (n+1)-th layer of light shielding film is expressed as Hn, and
a length of a deviation between said light shield in said n-th layer of light shielding film and said light shield in said (n+1)-th layer of light shielding film in a horizontal direction is expressed as dn+1,
said n-th layer of light shielding film and said (n+1)-th layer of light shielding film is placed to satisfy {(S+L−dn+1)(Tn+Tn+1+Hn)/(Tn+1+Hn)}>(2S+L−dn+1).

16. The solid-state imaging device according to claim 11, wherein
said plural layers of light shielding film are placed
so that a setting direction of a light shield and a space part in an (n+1)-th layer of light shielding film cross at right angles a setting direction of a light shield and a space part in an n-th layer light shielding film in a plane view.

17. The solid-state imaging device according to claim 16, wherein
said plural layers light shielding film are placed
so that a space part and a light shield in an (n+2)-th layer of light shielding film covers a part corresponding to upper sides of said light shield and said space part in said n-th layer light shielding film, respectively.
